(19) United States
(12) Patent Application Publication
(10) Pub. No.: US 2023/0092459 A1
(43) Pub. Date: Mar. 23, 2023

(54) Purcell-Effect-Enhanced Organic Light Emitting Diodes with Sub-Electrode Microlens Array

(71) Applicant: The Regents of the University of Michigan, Ann Arbor, MI (US)

(72) Inventors: Haonan Zhao, Ann Arbor, MI (US); Claire Arneson, Ann Arbor, MI (US); Stephen R. FORREST, Ann Arbor, MI (US)

(21) Appl. No.: 17/932,475

(22) Filed: Sep. 15, 2022

Related U.S. Application Data
(60) Provisional application No. 63/247,523, filed on Sep. 23, 2021.

(51) Int. Cl. H01L 51/52

(52) U.S. Cl. CPC H01L 51/5275; H01L 51/5215; H01L 51/5271; H01L 51/5234; H01L 51/5265

(57) ABSTRACT

An organic light emitting device (OLED) comprises a substrate layer, a sub-electrode microlens array (SEMLA) at least partially embedded in the substrate layer comprising a plurality of microlenses, a first electrode layer over the substrate layer, a light emitting layer over the first electrode layer, and a second electrode layer over the light emitting layer. The device can further include a distributed Bragg reflector (DBR) layer between the substrate and first electrode layers and/or a Purcell Factor (PF) enhancement layer over the second electrode layer, comprising at least one layer pair including a silver mirror electrode and a metal-dielectric layer. Related methods are also disclosed.

### CROSS-REFERENCE TO RELATED APPLICATIONS

This application claims priority to U.S. provisional application No. 63/247,523 filed on Sep. 23, 2021, incorporated herein by reference in its entirety. U.S. Department of Energy. The government has certain rights in the invention.

### STATEMENT REGARDING FEDERALLY SPONSORED RESEARCH OR DEVELOPMENT

This invention was made with government support under DE-EE0009166 awarded by the U.S. Department of Energy and under DE-EE0009688 awarded by the

### BACKGROUND OF THE INVENTION

Optoelectronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

Previous studies have shown that phosphorescent OLEDs suffer from triplet-triplet annihilation (TTA) and triplet-polaron annihilation (TPA) due to the long lifetime of triplets. Use of a cavity confined structure can increase the radiative decay rate of a triplet exciton, (known as the Purcell effect), reduce triplet exciton density in the emission layer, and prolong the device operational lifetime. However, light energy can become trapped in the form of a trapped substrate mode leading to a non-optimal angular emission profile. Thus, there is a need in the art for improvements in OLED devices

### SUMMARY OF THE INVENTION

Some embodiments of the invention disclosed herein are set forth below, and any combination of these embodiments (or portions thereof) may be made to define another embodiment.

In one aspect, an organic light emitting device (OLED) comprises a substrate layer, a sub-electrode microlens array (SEMLA) at least partially embedded in the substrate layer comprising a plurality of microlenses, a distributed Bragg reflector (DBR) layer positioned over the substrate layer, a first electrode layer positioned over the DBR layer, a light emitting layer positioned over the first electrode layer, and a second electrode layer positioned over the light emitting layer.

In one embodiment, the device further comprises a Purcell Factor (PF) enhancement layer over the second electrode layer, comprising at least one sub-layer pair including a silver mirror electrode and a metal-dielectric layer. In one embodiment, the PF enhancement layer further comprises a plurality of alternating Ag and dielectric sub-layers. In one embodiment, the SEMLA is etched into the substrate layer. In one embodiment, the SEMLA is fully embedded in the substrate layer. In one embodiment, the light emitting layer is disposed within a cavity, wherein the cavity is configured to produce in-plane light. In one embodiment, the SEMLA is configured to outcouple the in-plane light.

In one embodiment, the first electrode layer is configured as an anode comprising an Ag:Cu thin sub-layer between first and second ITO sub-layers. In one embodiment, the second electrode layer is configured as a cathode comprising an Ag:Cu thin layer or pure Ag thin layer stabilized bi Ti or Al. In one embodiment, the SEMLA is configured to modify an index of refraction of the substrate to an index in the range of 1.65 to 1.75. In one embodiment, the SEMLA comprises an array of hemispheres filled with a high-index polymer matching layer. In one embodiment, the hemispheres have a radius of 1 μm to 20 μm. In one embodiment, the high index polymer matching layer has an index of refraction of 1.7 to 2.0, and a transmission greater than 90%.

In one embodiment, the high-index polymer matching layer includes a flat surface configured for depositing organics. In one embodiment, the device has a near Lambertian angular emission profile. In one embodiment, the device is at least one type selected from the group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display having an active area with a primary diagonal of 2 inches or less, a 3-D display, a virtual reality or augmented reality display, a vehicle, a video wall comprising multiple displays tiled together, a theater or stadium screen, and a sign.

In one embodiment, the device has a maximum outcoupling efficiency of about 40%. In one embodiment, the device has a Purcell factor of about 5. In one embodiment, wherein the SEMLA layer has a thickness of 1 μm to 20 μm.

In another aspect, an organic light emitting device (OLED) production method comprises providing a substrate layer, etching a sub-electrode microlens array (SEMLA) into the substrate layer, depositing a distributed Bragg reflector (DBR) layer over the substrate layer, depositing a first electrode layer over the DBR layer, depositing a light emitting layer over the first electrode, depositing a second electrode layer over the light emitting layer, and depositing a Purcell Factor (PF) enhancement layer over the second electrode layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a block diagram depicting an exemplary organic light emitting device (OLED) in accordance with some embodiments.

FIG. 2 is a block diagram depicting an exemplary inverted organic light emitting device that does not have a separate electron transport layer in accordance with some embodiments.

FIGS. 3A through 3C depict exemplary structures for a cavity OLED in accordance with some embodiments.

FIGS. 4A and 4B depict exemplary device structure schematics on a SEMLA substrate in accordance with some embodiments. FIG. 4C depicts an exemplary hexagonal SEMLA array in accordance with some embodiments.

FIG. 5 is a plot depicting exemplary Purcell Factor and outcoupling efficiency in the emission layer (EML) of an example Purcell-effect-enhanced device in accordance with some embodiments.

FIG. 6 is a plot depicting exemplary energy transport coupling efficiency to different channels of an isotropic dipole in the EML of a Purcell-effect-enhanced device in accordance with some embodiments.

FIG. 7 is a plot depicting exemplary angular emission profile for an isotropic dipole in the example device profile in accordance with some embodiments. The profile in glass substrate and out of substrate (air) are shown, in comparison with the standard Lambertian.

FIG. 8 is a plot depicting exemplary energy transport efficiency in an example Purcell-effect-enhanced OLED with a Purcell factor of about 5 and SEMLA in accordance with some embodiments. The maximum outcoupling efficiency is about 40%.

FIGS. 9A and 9B are plots depicting exemplary energy transport in a cavity OLED versus dipole orientation in accordance with some embodiments. A higher horizontal dipole ratio results in a higher fraction of substrate and air modes, while decreasing the fraction of SPP modes. FIG. 9A: cavity OLED without SEMLA. FIG. 9B: cavity OLED with SEMLA substrate.

FIGS. 10A through 10C are plots depicting exemplary material properties for the exemplary OLED in accordance with some embodiments.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems and methods of Purcell-Effect-Enhanced organic light emitting devices with sub-electrode microlens arrays. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

Referring now in detail to the drawings, in which like reference numerals indicate like parts or elements throughout the several views, in various embodiments, presented herein are Purcell-Effect-Enhanced organic light emitting devices with sub-electrode microlens arrays and related methods.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

As used herein, and as would be understood by one skilled in the art, “HATCN” (referred to interchangeably as HAT-CN) refers to 1,4,5,8,9,11-Hexaazatriphenylenehexacarbonitrile.

“TAPC” refers to 4,4′-Cyclohexylidenebis[N,N-bis(4-methylphenyl)aniline]. “B3PYMPM” refers to 4,6-Bis(3,5-di(pyridin-3-yl)phenyl)-2-methylpyrimidine. “BPyTP2” refers to 2,7-Bis(2,2′-bipyridin-5-yl)triphenylene. “LiQ” refers to Lithium Quinolate. “ITO” refers to Indium Tin Oxide. “CBP” refers to 4,4′-Bis(N-carbazolyl)-1,1′-biphenyl. “Ir(ppy)2acac” refers to bis[2-(2-pyridinyl-N)phenyl-C](acetylacetonato)iridium(III).

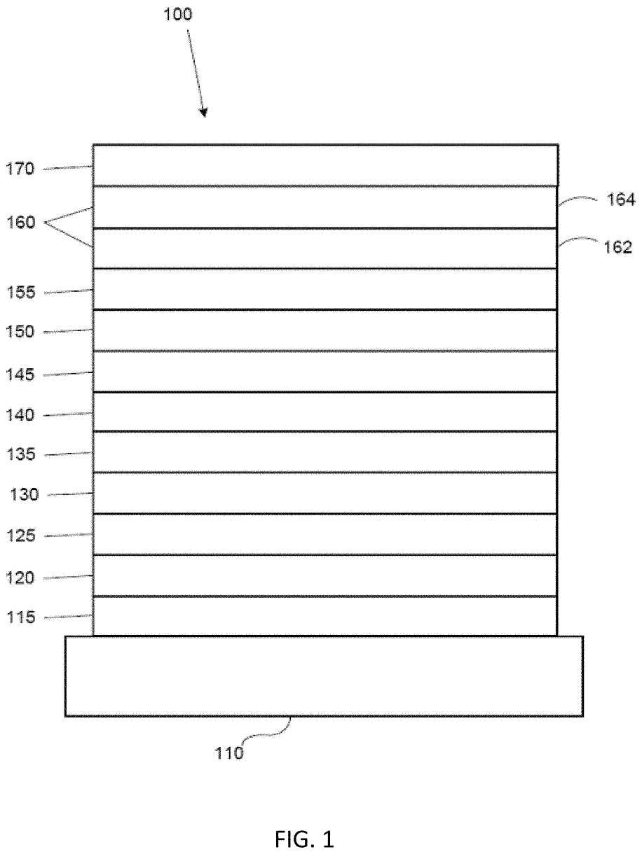

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

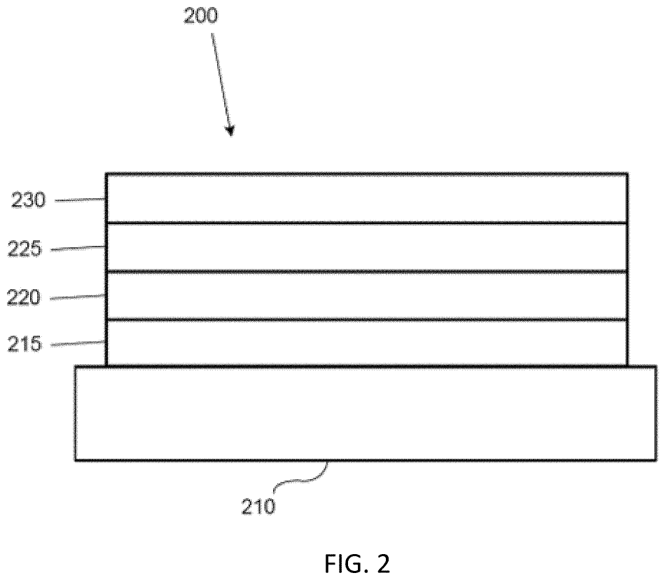

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIG. 1 and FIG. 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Certain embodiments of the disclosure relate to a light emitting device comprising an emissive layer (EML) spaced far from a cathode as described herein. Conventional organic light emitting devices typically place the EML near a metal cathode which incurs plasmon losses due to near field coupling. To avoid exciting these lossy modes it is necessary to space the EML far from the cathode. However, utilizing a thick electron transport layer (ETL) can be problematic due to changes in charge balance and increased resistivity. These problems can be overcome by utilizing a charge generation layer, for example a charge generation layer comprising at least one electron transport layer and at least one hole transport layer, to convert electron into hole current. This allows the use of higher mobility hole transporting materials and maintains the charge balance of the device. In some embodiments, the charge generation layer may be replaced or combined with any other layer capable of conducting electrons.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

Conventional OLEDs typically have an optical outcoupling efficiency of around 20% or less. Most of the light is trapped in surface plasmon modes (SPPs) at the metal electrode surface and in waveguide modes due to the high refractive index of organic materials and transparent electrodes. Conventional techniques to eliminate SPPs use a thick organic layer between the emissive layer(s) and a metal electrode. However, the thicker organic layers introduce more waveguided light, which results in little or no net change to the light extraction efficiency.

Embodiments disclosed herein address this and other issues with conventional OLED structure by including a microlens array disposed between the OLED substrates and transparent electrodes for both bottom and top-emitting OLEDs. The microlens array also may be at least partially embedded within the substrate. It has been found that high refractive index sub-electrode microlens arrays embedded in a substrate and beneath the transparent bottom electrode of OLEDs as disclosed herein may redirect up to 100% of the light confined in organic and electrode layers toward the substrate. The placement of the microlens array below the OLED as disclosed herein allows for freedom in OLED design and fabrication; the nonintrusive flat upper surface of the lens array provides a surface similar to that of a conventional flat glass or plastic substrate. Both monochromatic and white PHOLEDs fabricated on SEMLA substrates with external outcoupling show extremely high efficiencies of ηEQE=70±4% with EF=2.8 for green and ηEQE=50±3% with EF=3.1 for the WOLED compared to analogous devices on conventional glass substrates. This is significantly more efficient light extraction than other reports of nonintrusive outcoupling structures. The blue shift eliminated at large angles along with no perceptible impact on image sharpness makes this method ideal for white light illumination and display applications. The spectrum of WOLEDs on SEMLA substrates remains identical with those on sapphire substrates, affording both higher efficiency and lower costs with no expense to performance or freedom in device design.

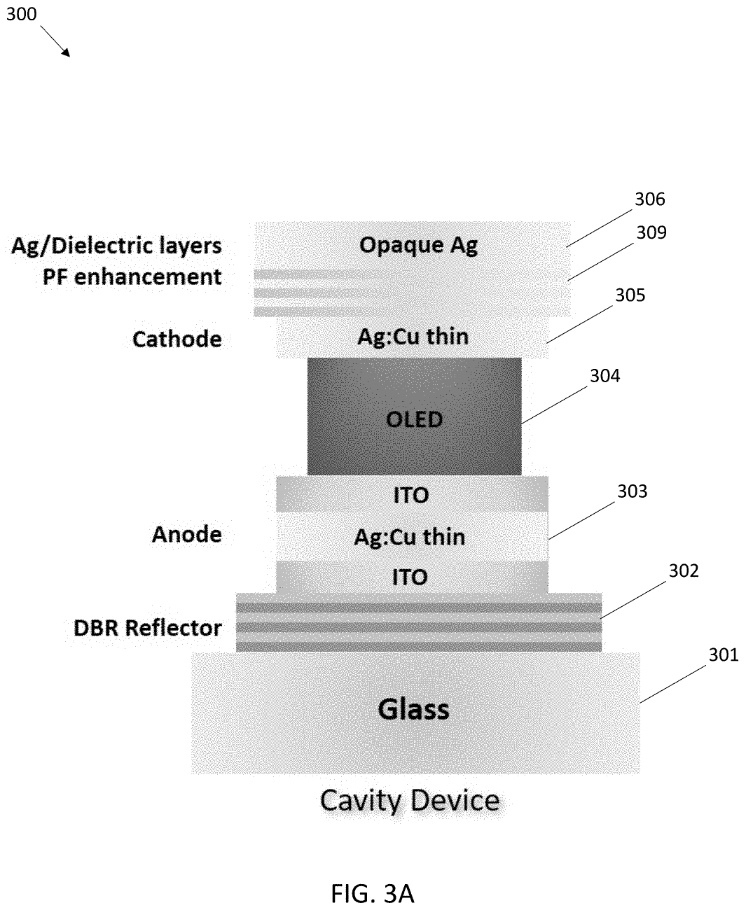

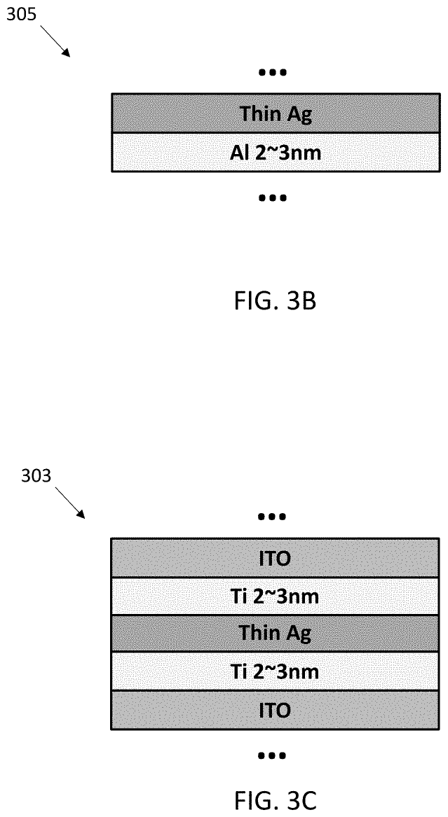

Referring now to FIGS. 3A-C and 4A-C, an exemplary organic light emitting device 300 (OLED) is shown. The device 300 may include a substrate layer 301, a sub-electrode microlens array (SEMLA) 307 at least partially embedded in the substrate layer 301 where the SEMLA 307 comprises a plurality of microlenses, a first electrode layer 303 positioned over the substrate layer 301, a light emitting layer 304 positioned over the first electrode layer 303, and a second electrode layer 305 positioned over the light emitting layer 304. In some embodiments, the light emitting layer 304 can be defined as an OLED layer. The device 300 can further include a distributed Bragg reflector (DBR) layer 302 positioned between the substrate 301 and first electrode layer 303. The device 300 can further include a Purcell Factor (PF) enhancement layer 306 over the second electrode layer 305. In some embodiments, the PF enhancement layer 306 comprises at least one sub-layer mirror pair 309 including a silver mirror electrode and a metal-dielectric layer. In some embodiments, the PF enhancement layer 306 comprises a plurality of alternating Ag and dielectric sub-layers.

In some embodiments the SEMLA 307 is etched into the substrate layer 301. In some embodiments, the light emitting layer 304 is disposed withing a cavity defined by all top structure sub-layers and bottom structure sub-layers. In some embodiments, Top structures include the second electrode (cathode) 305, sub-layer mirror pair (Ag/dielectric layers) 309 and the finally the Purcell factor enhancement layer (opaque Ag) 306. Bottom structures include the first electrode (anode) 303 and the DBR 302. In some embodiments, each layer or sub-layer in the top and/or bottom structures is designed to slice the mode volume layer-by-layer for Purcell enhancement or outcoupling purposes, where mode volume physically defines the optical cavity. In some embodiments, the cavity is configured to produce in-plane light. The SEMLA 307 may be configured to outcouple the in-plane light. The SEMLA may further be configured to modify an index of refraction of the substrate 301 to an index in the range of 1.65 to 1.75. In some embodiments, the SEMLA comprises an array of hemispheres filled with a high-index polymer matching layer. The hemispheres may have a radius of 1 μm to 20 μm. In some embodiments, the SEMLA 307 has a thickness of 1 μm to 20 μm.

In some embodiments, the first electrode layer 303 is configured as an anode comprising an Ag:Cu thin sub-layer between first and second ITO sub-layers. In some embodiments, the second electrode layer 305 is configured as a cathode comprising an Ag:Cu thin layer. As shown in FIG. 3B, in some embodiments the second electrode 305 comprises a cathode comprising a pure Ag thin layer stabilized by Ti or Al. As shown in FIG. 3C, in some embodiments the first electrode 303 comprises an anode comprising a first ITO layer, a first Ti or Al stabilization layer above the first ITO layer, a pure Ag thin layer above the first stabilization layer, a second first Ti or Al stabilization layer above the Ag thin layer, and a second ITO layer above the second stabilization layer.

In some embodiments the high index polymer matching layer comprises a material with a refractive index equal to or greater than the refractive index of the organic layers, from approximately 1.7-2.0, and high transmission, greater than 90%. Some example materials include optical adhesives or epoxies, such as Norland Optical Adhesive 170 and Pixellligent PixNIL, and any other suitable high index materials that can be deposited in micron-scale thick layers. The high-index polymer matching layer may include a flat surface configured for depositing organics.

In some embodiments, the device 300 has a near Lambertian angular emission profile. In some embodiments, the device 300 is at least one type selected from the group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display having an active area with a primary diagonal of 2 inches or less, a 3-D display, a virtual reality or augmented reality display, a vehicle, a video wall comprising multiple displays tiled together, a theater or stadium screen, and a sign.

In some embodiments, the device 300 has a maximum outcoupling efficiency of about 40% and/or a Purcell factor of about 5.

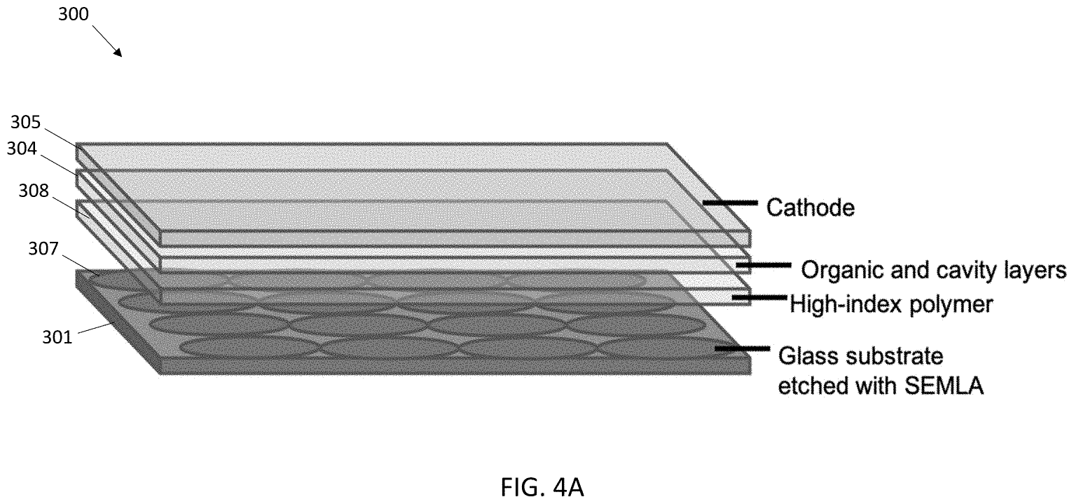

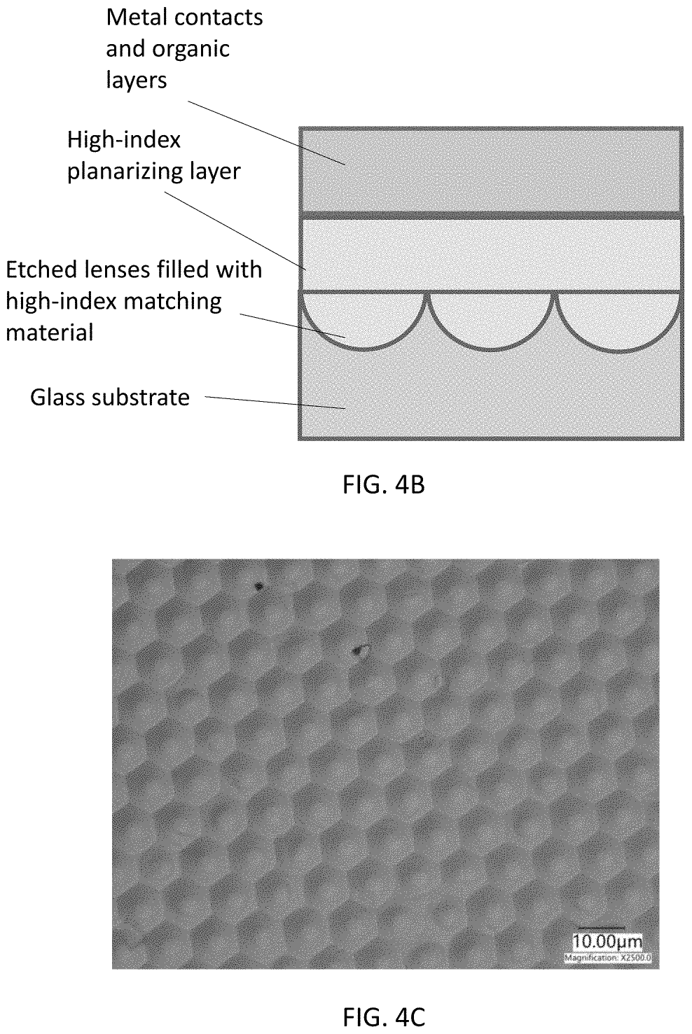

Long device lifetime, high outcoupling efficiency, and Lambertian emission are favored for display and lighting purposes. In some embodiments, to achieve high outcoupling efficiency and Lambertian emission, the device 300 includes an external enhancement layer comprising a sub-electrode microlens array (SEMLA) 307. In some embodiments, the SEMLA 300 comprises of an array of hemispheres that are filled with a high-index polymer matching layer 308 to create a flat surface upon which organics can be deposited, as is shown in FIGS. 4A and 4B. The SEMLA 307 changes the index of refraction of the substrate 301 material from that of glass, nglass=1.5, to nSEMLA=1.70, which is close to the typical index of refraction of organic materials. This forces a decrease in the waveguide modes present in the device, resulting in higher increased coupling to air and substrate modes. Air modes and substrate modes are both outcoupled by the SEMLA 307 and contribute to the external quantum efficiency (EQE) of the device. Additionally, the use of SEMLA 307 results in a more Lambertian angular emission profile, compared to that of a device on a plain glass substrate.

In some embodiments, a hexagonal close-packed lens arrangement with no planar spacing between lenses is optimal (see FIGS. 4A-4C). In some embodiments, the microlens array comprises multiple layers including a glass substrate with a planar bottom surface and top surface with etched hemispheres, etched lenses filled with a high-index material, and an additional layer of high-index material forming a planar surface above the lenses.

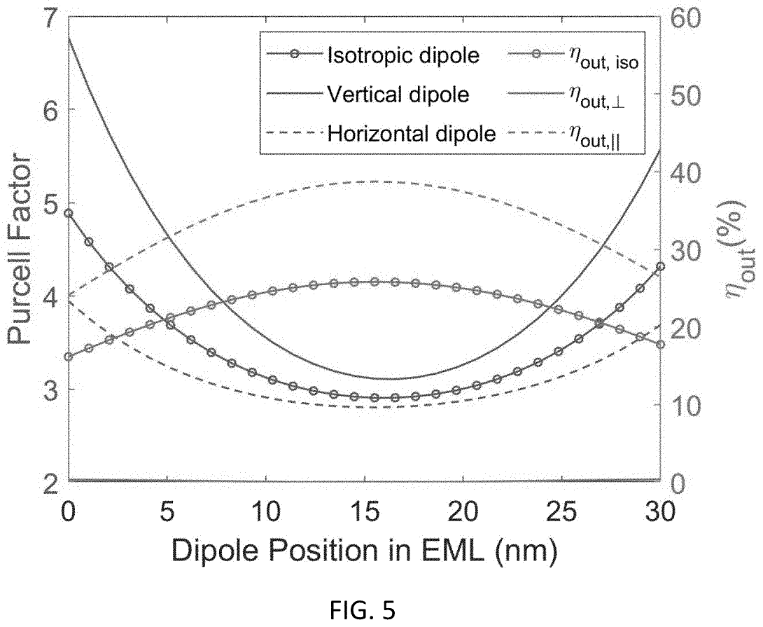

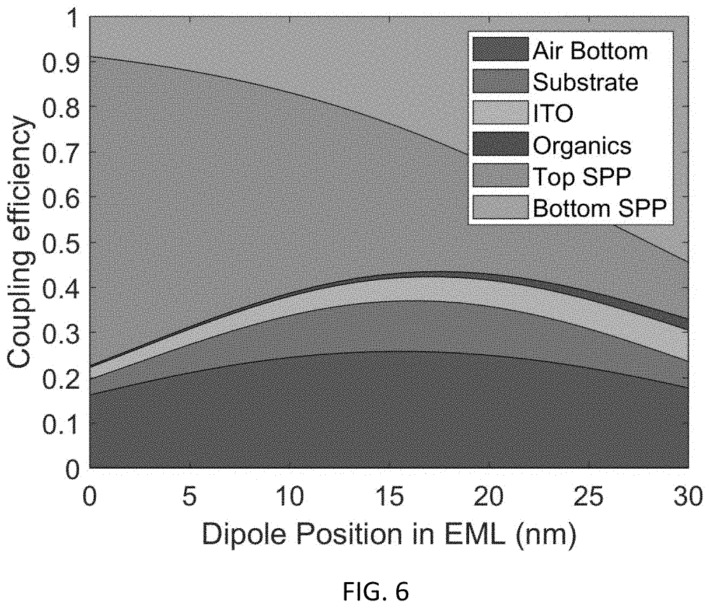

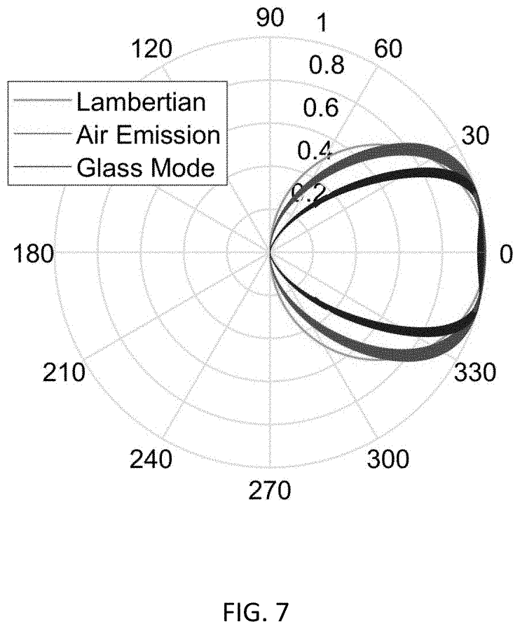

In some device embodiments, multiple silver surfaces in the near-field region are used to maximize the radiative coupling between the exciton energy and silver surface plasmon polariton (SPP) modes. According to simulations, this archetypal structure can achieve a Purcell factor of approximately 5, as is shown in FIG. 5. As a result, the radiative lifetime of triplets in the cavity is reduced by a factor of 5 compared to the lifetime in vacuum or solution. In this structure, the main proportion of the total energy dissipation is coupled into SPP modes, resulting in an outcoupling efficiency of approximately 20%, as is shown in FIGS. 5 and 6. Additionally, the presence of cavity effects results in a narrow angular emission profile for cavity OLEDs, compared to the Lambertian profile, as is shown in FIG. 7.

In operation, the OLED 304 emits light directly or indirectly at least in the direction of the microlens array 307, though generally the OLED 304 may have any stack structure as disclosed herein and as known in the art. Such an array may be referred to as a sub-electrode microlens array (SEMLA) since it is positioned below the bottom electrode 303. It will be understood that the microlens array 307 is not shown to scale relative to the OLED and the features may be exaggerated for purposes of illustration. In some embodiments, the microlens array 307 can be a micron-scale array.

The refractive index of materials for the microlens 307 may be the same, slightly lower, or slightly higher than the organic materials and the electrodes in the OLED, typically in the range 1.6-2. More generally, the microlens array 307 should have an index of refraction higher than the index of refraction of the substrate, where in some embodiments this is preferably at least 1% greater than the index of refraction of the substrate. It may be preferred for the microlens array to have a relatively high index, preferably not less than 1.7, not less than 1.8, or not less than 1.9. Alternatively or in addition, the substrate 301 may have an index of refraction in the range of 1.4-1.5, such as may be expected for glass or similar substrates. In some configurations, one or more layers of the OLED also may have a relatively high index, such as not less than 1.7. The upper side of the microlens array structures may be planar to allow for deposition of organic devices. In this way, the outcoupling structures do not have any appreciable impact on the electrical properties of the devices. For bottom-emitting devices, microlens arrays may be fabricated directly on to or within the glass substrates. For top-emitting devices, a reflective layer may be deposited between the substrate 301 and the microlens array 307. The reflective layer may be a reflective metal, such as silver or aluminum, a transparent dielectric (typically for bottom-emitting configurations), or any other suitable reflective material. In some embodiments, the reflective layer is at least 30% reflective, 40% reflective, 50% reflective, or more within the primary emission spectrum of the OLED. The reflective layer also may be or act as an environmental barrier, such as a portion of the encapsulation of the OLED/MLA arrangement.

In some embodiments, the microlens array 307 may be at least partially disposed within, i.e., embedded in the substrate 301, such that it is at least partially below the surface of the substrate closest to the OLED 304. The microlens array 307 may be partially embedded within the substrate 301, or it may be fully embedded within the substrate 301 such that no non-planar portion of the microlens array 307 extends above the surface of the substrate closest to the OLED. That is, if the microlens array 307 is entirely embedded within the substrate, the curved or otherwise non-planar surfaces of the array may be below the surface of the substrate closest to the OLED. In some embodiments, it may be preferred for the microlens array 307 to be entirely embedded within the substrate. Alternatively, for hemispherical microlenses the microlenses may be disposed a distance equal to or greater than ¼ of a peak wavelength of light emitted by the OLED. The microlens array 307 may be embedded within the substrate 301 such that a distance from the surface of the substrate closest to the OLED to the base of the microlens array may be in the range 10 nm-30 μm. As used herein, the “base” of the microlens array refers to the planar surface of the microlens array, i.e., the base of the plurality of lenses in the array. The microlenses themselves may be on the order of 10 μm or less, or generally may be of micron scale.

The spacer layer may include the same material as in the microlens array 307. In some embodiments, it may be preferred for the spacer layer to have an index of refraction close to or the same as that of the microlens array 307. The spacer layer also may function as a planarizing layer, such as to prevent the requirement of fabricating an OLED on a non-uniform base of a microlens array due to manufacturing nonuniformities, inherent gaps between non-adjacent lenses in the array, or the like. The spacer layer may be fabricated separately or continuously with the microlens array 307, such that there is not a discernable seam or other interface between the two. The spacer/planarizing layer may have a refractive index within about 10% of the refractive index of the microlens array or, preferably, it may have an index equal to that of the microlens array. The spacer layer may be distinguished from the microlens array 307 in that the spacer layer may be uniform across its thickness, i.e., in a direction normal to the substrate 301. In contrast, the microlens array exhibits non-uniformities across its thickness. For example, as explained in further detail herein, the microlens array may include multiple hemispherical lenses or other structures that have space between at least part of them at various points in the microlens array layer, whereas the spacer layer has no such structures.

The shape of the microlenses in the array may be a hemisphere, tetrahedron, or any other suitable shape. It may be desirable for the microlens array to be made from one or more materials having a comparable refractive index to organic materials and transparent electrodes in the active region of the OLED to eliminate the waveguide modes.

In one embodiment, the light emitting layer 304 may include a stack of light emitting sublayers. In another embodiment, the light emitting layer 304 includes light emitting sublayers that are arranged in a horizontally adjacent pattern, e.g., to from adjacent sub-pixels or an electronic display. For example, the light emitting body can includes separate red and green light emitting sublayers in a stacked or side-by-side (i.e., adjacent) arrangement.

In one embodiment, the device 300 is a white-light organic electroluminescent device (WOLED).

Devices of the present disclosure may comprise one or more electrodes, some of which may be fully or partially transparent or translucent. In some embodiments, one or more electrodes comprise indium tin oxide (ITO) or other transparent conductive materials. In some embodiments, one or more electrodes may comprise flexible transparent and/or conductive polymers.

Layers may include one or more electrodes, organic emissive layers, electron- or hole-blocking layers, electron- or hole-transport layers, buffer layers, or any other suitable layers known in the art. In some embodiments, one or more of the electrode layers may comprise a transparent flexible material. In some embodiments, both electrodes may comprise a flexible material and one electrode may comprise a transparent flexible material.

An OLED fabricated using devices and techniques disclosed herein may have one or more characteristics selected from the group consisting of being flexible, being rollable, being foldable, being stretchable, and being curved, and may be transparent or semi-transparent. In some embodiments, the OLED further comprises a layer comprising carbon nanotubes.

In some embodiments, an OLED fabricated using devices and techniques disclosed herein further comprises a layer comprising a delayed fluorescent emitter. In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

In some embodiments, an organic light emitting device (OLED) production method comprises providing a substrate layer 301, etching a sub-electrode microlens array (SEMLA) 307 into the substrate layer 301, depositing a distributed Bragg reflector (DBR) layer 302 over the substrate layer 301, depositing a first electrode layer 303 over the DBR layer 302, depositing a light emitting layer 304 over the first electrode 303, depositing a second electrode layer 305 over the light emitting layer 304, and/or depositing a Purcell Factor (PF) enhancement layer 306 over the second electrode layer 305.

An OLED fabricated according to techniques and devices disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

The CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### Experimental Examples

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

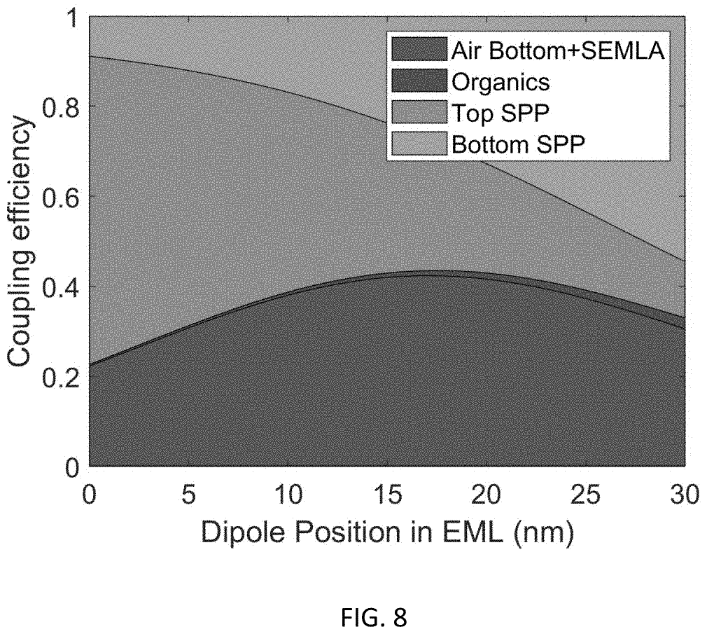

Example simulated device characteristics are shown in FIGS. 5-10. The simulated device utilized silver/dielectric alternating layers as both electrodes for a phosphorescent OLED to enhance cavity effects. Next, the conventional glass substrate was replaced with a SEMLA to couple more optical power from the trapped waveguided modes into extractable substrate and air modes, while also widening the angular emission profile. Green's function analysis was used to calculate the electric field distribution throughout a multilayer device. These simulations have shown that by utilizing this structure, one can achieve an outcoupling efficiency as high as 40%, as is shown in FIG. 8, while maintaining a Purcell factor of around 5.

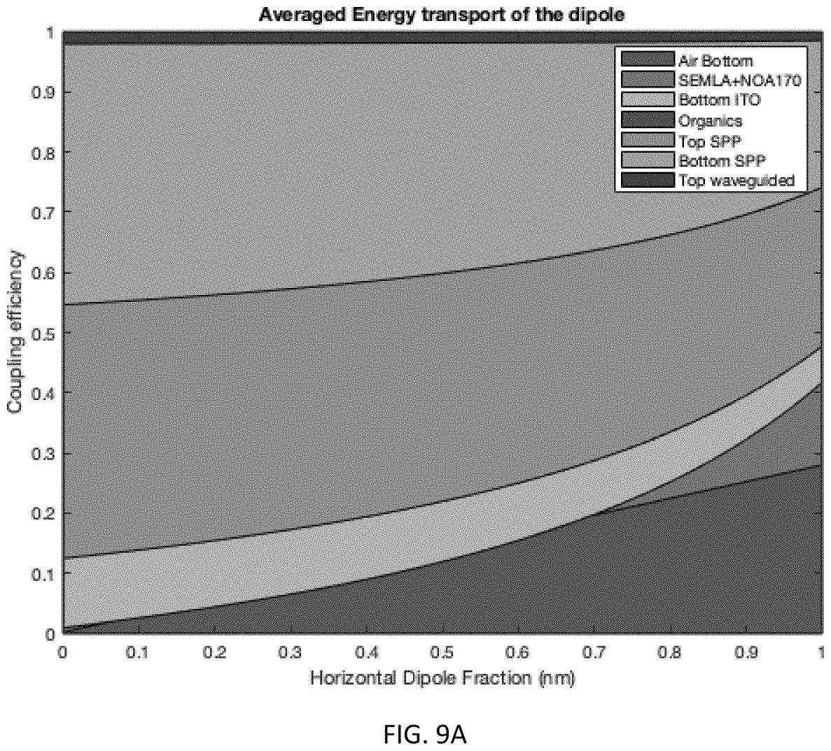

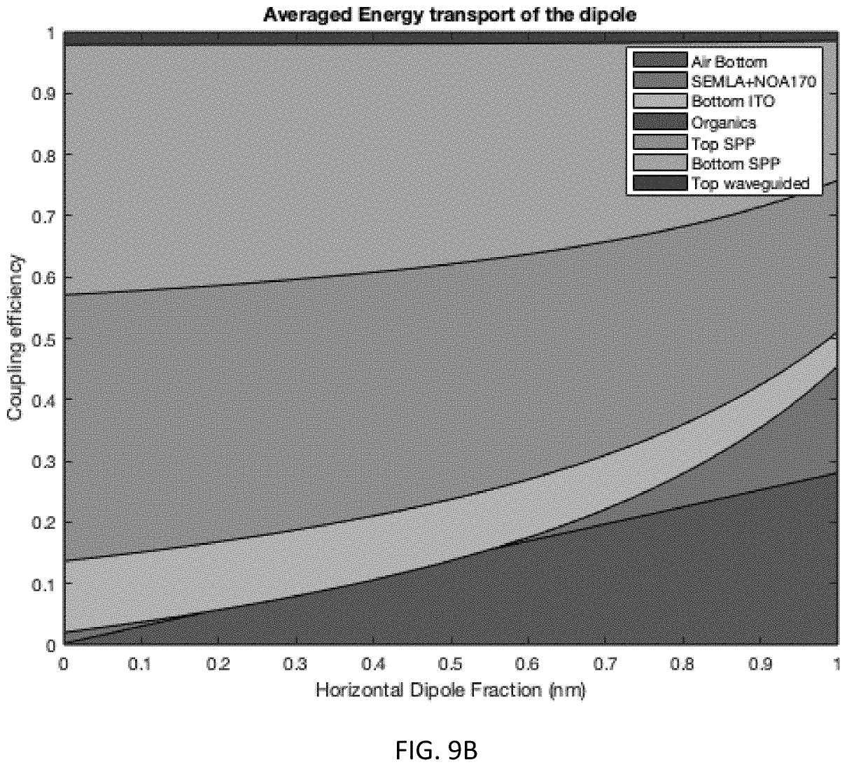

As shown in FIGS. 5 and 6, the near-field SPP coupling to both silver electrodes increases the radiation decay rate up to five times as that in vacuum or solution. The energy transport to outcoupled air mode takes up to 20% of the total exciton energy. The cavity length is designed to optimize the outcoupling efficiency, Purcell factor, and electrical transport. The energy trapped in the glass substrate and the layers below silver electrode accounts for approximately 20% of optical power, which eventually will dissipate through other channels such as ITO absorption, metal absorption, and substrate waveguide modes. With the metal cavity present, the angular emission is distorted from the Lambertian profile in either air or glass, as is shown in FIG. 7. By applying the SEMLA to the glass substrate, one can extract almost all the trapped energy in the substrate and ITO layer below the silver anode, and, in the meantime, randomly diffuse the light emission to create a Lambertian profile. Since SPP modes only couple to the TM waves, the vertical dipoles couple almost all their power to the SPP channel, while horizontal dipoles partially couple to SPP modes and contribute nearly all the outcoupling efficiency. With higher horizontal dipole ratio, the energy trapped in the substrate modes are prominently larger, leading to an unwanted energy loss. Thus, applying a SEMLA can further extract the horizontal dipole radiation power out of the device, as is shown in FIGS. 9A and 9B.

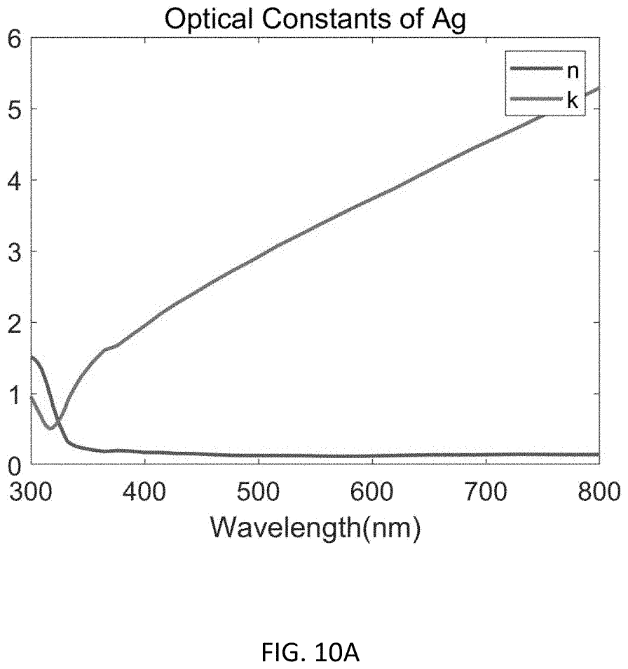

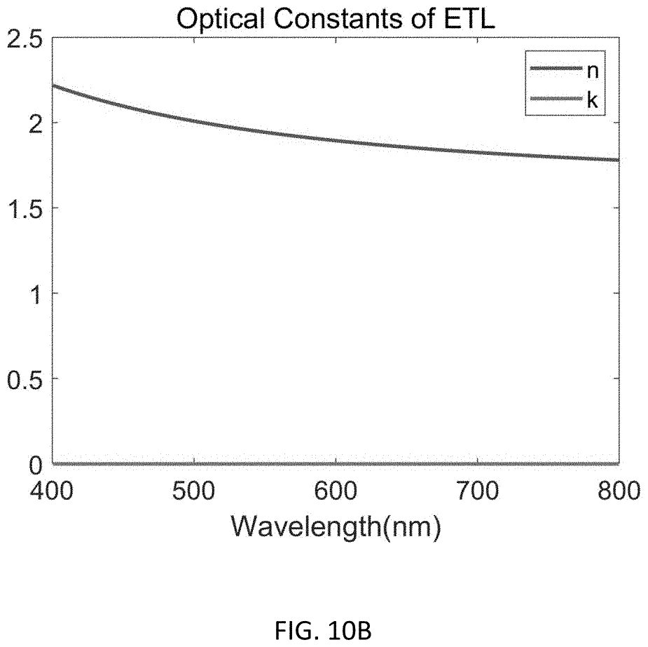

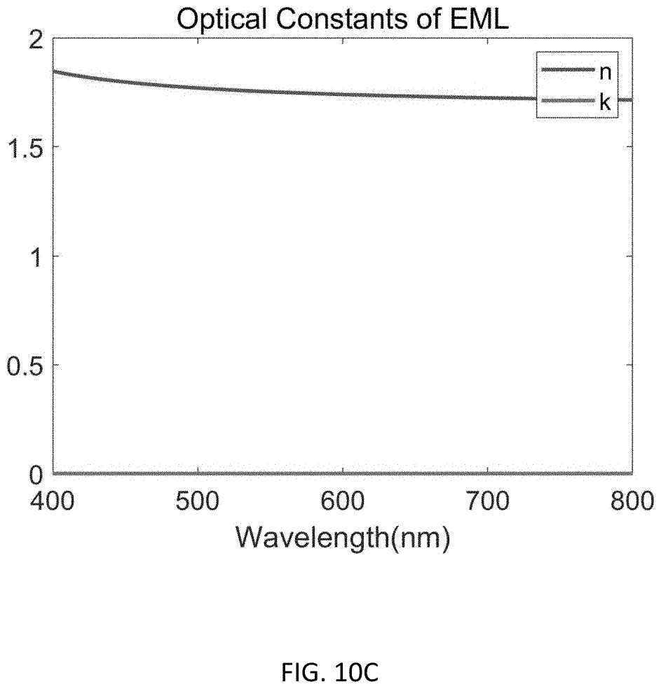

Details of example thicknesses, indices of refraction, and materials for each layer are shown in FIGS. 10A-10C and FIGS. 3B-3C. Example values for the top cavity layers are shown in FIG. 10A, and for the organics are shown in FIGS. 10B-10C. In some embodiments, the organics have an index of refraction of about 1.7. In some embodiments, the bottom cavity layers can comprise ITO with an index of refraction of about 1.9, SiO₂ with and index of refraction of about 1.45, and/or SiNₓ with and index of refraction of about 2.0. In some embodiments, the SEMLA high index matching layer has a thickness of 1 μm to 20 μm, and an index of refraction of greater than or equal to 1.7. In some embodiments, the etched glass substrate has a thickness of 100 μm to 700 μm, and an index of refraction of 1.4 to 1.5.

By applying both methods, one can achieve a Purcell factor of 4.8 and outcoupling efficiency of 24% for a conventional OLED, and a Purcell factor of 3.5 and outcoupling efficiency of 36% for an OLED with a graded EML, where the Purcell factor and outcoupling efficiency are averaged over EML position.

The following publications are each hereby incorporated by reference in their entirety:
Baldo, M., Adachi, C., and Forrest, S. R. (2000) Transient analysis of organic electrophosphorescence. II. Transient analysis of triplet-triplet annihilation. Physical Review B 62(16), 10967.
Qu, Y., Kim, J., Coburn, C., & Forrest, S. R. (2018). Efficient, nonintrusive outcoupling in organic light emitting devices using embedded microlens arrays. ACS Photonics, 5(6), 2453-2458.
Celebi, K., Heidel, T. D., & Baldo, M. A. (2007). Simplified calculation of dipole energy transport in a multilayer stack using dyadic Green's functions. Optics Express, 15(4), 1762-1772.
U.S. patent Ser. No. 11/362,311, “Sub-electrode microlens array for organic light emitting devices”

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An organic light emitting device (OLED), comprising:
a substrate layer;
a sub-electrode microlens array (SEMLA) at least partially embedded in the substrate layer comprising a plurality of microlenses;
a distributed Bragg reflector (DBR) layer positioned over the substrate layer;
a first electrode layer positioned over the DBR layer;
a light emitting layer positioned over the first electrode layer; and
a second electrode layer positioned over the light emitting layer.

2. The device of claim 1, further comprising a Purcell Factor (PF) enhancement layer over the second electrode layer, comprising at least one sub-layer pair including a silver mirror electrode and a metal-dielectric layer.

3. The device of claim 2, wherein the PF enhancement layer further comprises a plurality of alternating Ag and dielectric sub-layers.

4. The device of claim 1, wherein the SEMLA is etched into the substrate layer.

5. The device of claim 1, wherein the SEMLA is fully embedded in the substrate layer.

6. The device of claim 1, wherein the light emitting layer is disposed within a cavity, wherein the cavity is configured to produce in-plane light.

7. The device of claim 6, wherein the SEMLA is configured to outcouple the in-plane light.

8. The device of claim 1, wherein the first electrode layer is configured as an anode comprising an Ag:Cu thin sub-layer between first and second ITO sub-layers.

9. The device of claim 1, wherein the second electrode layer is configured as a cathode comprising an Ag:Cu thin layer or pure Ag thin layer stabilized bi Ti or Al.

10. The device of claim 1, wherein the SEMLA is configured to modify an index of refraction of the substrate to an index in the range of 1.65 to 1.75.

11. The device of claim 1, wherein the SEMLA comprises an array of hemispheres filled with a high-index polymer matching layer.

12. The device of claim 11, wherein the hemispheres have a radius of 1 μm to 20 μm.

13. The device of claim 11, wherein the high index polymer matching layer has an index of refraction of 1.7 to 2.0, and a transmission greater than 90%.

14. The device of claim 11, wherein the high-index polymer matching layer includes a flat surface configured for depositing organics.

15. The device of claim 1, wherein the device has a near Lambertian angular emission profile.

16. The device of claim 1, wherein the device is at least one type selected from the group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a mobile phone, a tablet, a phablet, a personal digital assistant (PDA), a wearable device, a laptop computer, a digital camera, a camcorder, a viewfinder, a micro-display having an active area with a primary diagonal of 2 inches or less, a 3-D display, a virtual reality or augmented reality display, a vehicle, a video wall comprising multiple displays tiled together, a theater or stadium screen, and a sign.

17. The device of claim 1, wherein the device has a maximum outcoupling efficiency of about 40%.

18. The device of claim 1, wherein the device has a Purcell factor of about 5.

19. The device of claim 1, wherein the SEMLA layer has a thickness of 1 μm to 20 μm.

20. An organic light emitting device (OLED) production method, comprising:
providing a substrate layer;
etching a sub-electrode microlens array (SEMLA) into the substrate layer;
depositing a distributed Bragg reflector (DBR) layer over the substrate layer:
depositing a first electrode layer over the DBR layer;
depositing a light emitting layer over the first electrode;
depositing a second electrode layer over the light emitting layer; and
depositing a Purcell Factor (PF) enhancement layer over the second electrode layer.
